(19) United States
(12) Patent Application Publication
(10) Pub. No.: US 2025/0122072 A1
(43) Pub. Date: Apr. 17, 2025

(54) DIFFERENTIAL DIRECTIONAL ACOUSTIC SENSOR DEVICE

(71) Applicant: Soundskrit Inc., Montreal (CA)

(72) Inventors: Benjamin Evans, Montreal (CA); Carly Stalder, Montreal (CA); Stephane Leahy, Montreal (CA); Sahil Gupta, Montreal (CA)

(21) Appl. No.: 18/913,431

(22) Filed: Oct. 11, 2024

Related U.S. Application Data
(60) Provisional application No. 63/590,333, filed on Oct. 13, 2023.

(51) Int. Cl. B81B 3/00; H04R 1/32

(52) U.S. Cl. CPC B81B 3/0021; H04R 1/326; B81B 2201/0257; B81B 2203/0118; B81B 2203/0136; B81B 2203/0353; B81B 2207/09; H04R 2201/003

(57) ABSTRACT

An acoustic sensor device includes a substrate and a first transducer supported by the substrate, the first transducer configured to generate a first output signal when exposed to a sound wave. The acoustic sensor device also include a second transducer supported by the substrate, the second transducer configured to generate a second output signal when exposed to a sound wave. The first transducer and the second transducer are configured such that the first output signal generated by the first transducer and the second output signal generated by the second transducer are opposite in polarity.

### CROSS-REFERENCES TO RELATED APPLICATIONS

This application claims the benefit of U.S. provisional application entitled “Differential MEMS Directional Microphone,” filed Oct. 13, 2023, and assigned Ser. No. 63/590,333, the entire disclosure of which is hereby expressly incorporated by reference.

### BACKGROUND OF THE DISCLOSURE

### Field of the Disclosure

The disclosure relates generally to acoustic sensor devices such as microelectromechanical system (MEMS) microphones.

### Brief Description of Related Technology

In some traditional omnidirectional acoustic sensor devices, such as omnidirectional microphones using microelectromechanical system (MEMS) transducers, a dual-backplate structure is used. A membrane is constructed that is free to vibrate between two fixed backplates. The membrane holds a bias voltage and induces a voltage or charge on the two backplates with an opposite polarity. This biasing creates a differential signal between the two backplates that can be amplified by an application-specific integrated circuit (ASIC) or other circuitry. When subtracting the two signals on the backplates, the signal is doubled due to the opposite polarity of the two signals. However, any common mode signals between the backplates effectively cancel out. Such differential configuration may be used, for example, to reduce distortion and non-linearities seen in the MEMS transducer, thus increasing the acoustic overload point of the microphone.

Some MEMS directional microphones employ a cantilever-based design using a moving cantilever with interdigitated fingers rather than fixed backplates as used in omnidirectional microphones. As a result, a traditional dual-backplate sensing architecture cannot be used to generate a differential signal.

### SUMMARY OF THE DISCLOSURE

In accordance with one aspect of the disclosure, an acoustic sensor device includes a substrate and a first transducer supported by the substrate, the first transducer configured to generate a first output signal when exposed to a sound wave. The acoustic sensor device also includes a second transducer supported by the substrate, the second transducer configured to generate a second output signal when exposed to the sound wave. The first transducer and the second transducer are configured such that the first output signal generated by the first transducer and the second output signal generated by the second transducer are opposite in polarity.

In accordance with another aspect of the disclosure, an acoustic sensor device includes a substrate and a first microelectromechanical system (MEMS) transducer supported by the substrate, the first MEMS transducer configured to generate a first output signal when exposed to a sound wave. The acoustic sensor device also includes a second MEMS transducer supported by the substrate, the second MEMS transducer configured to generate a second output signal when exposed to the sound wave. The first MEMS transducer and the MEMS second transducer are configured such that the first MEMS transducer and the second MEMS transducer move in opposite directions with respect to each other when exposed to the sound wave.

In connection with any one of the aforementioned aspects, the devices and/or methods described herein may alternatively or additionally include or involve any suitable combination of one or more of the following aspects or features. Each of the first transducer and the second transducer comprises a microelectromechanical system (MEMS) transducer. Each of the first transducer and the second transducer comprises a cantilever structure. The first transducer comprises a first cantilever having a first initial deflection on one side of the first cantilever. The second transducer comprises a second cantilever having a second initial deflection on one side of the second cantilever. The first initial deflection of the first cantilever and the second initial deflection of the second cantilever are configured to be within a predetermined range with respect to each other. The acoustic sensor device further includes a package, wherein the substrate forms one side of the package, and wherein the package further includes a lid placed over the substrate, the lid encapsulating the first transducer and the second transducer inside package. The acoustic sensor device further includes a first sound port configured to expose one side of the first transducer to an ambient environment and a second sound port configured to expose one side of the second transducer to the ambient environment.

The first sound port is formed in the substrate and the second sound port is formed in the substrate such that the first sound port and the second sound port are formed on a same side of the package of the acoustic sensor device. The first transducer comprises a first cavity placed over the first sound port formed in the substrate and the second transducer comprises a second cavity placed over the second sound port formed in the substrate. The first transducer and the second transducer are configured such that the first transducer and the second transducer move in opposite directions with respect to each other when exposed to the sound wave. The acoustic sensor device of claim 1 further includes an integrated circuit coupled to the first transducer and the second transducer. The integrated circuit is configured to: receive the first output signal generated by the first transducer, wherein the first output signal has a first amplitude; receive the second output signal generated by the second transducer, wherein the second output signal has a second amplitude; and generate a composite output signal based on the first output signal and the second output signal, wherein the composite output signal has a third amplitude that is i) greater than the first amplitude of the first output signal and ii) greater than the second amplitude of the second output signal. The integrated circuit is configured to generate the composite output signal by performing a subtraction operation between the first output signal generated by the first transducer and the second output signal generated by the second transducer. The first transducer and the second transducer are configured such that the first amplitude of the first output signal and the second amplitude of the second output signal are equal to each other, and wherein the third amplitude of the composite output signal is greater than each of the first amplitude of the first output signal and the second amplitude of the second output signal by a factor of two.

### BRIEF DESCRIPTION OF THE DRAWING FIGURES

For a more complete understanding of the disclosure, reference should be made to the following detailed description and accompanying drawing figures, in which like reference numerals identify like elements in the figures.

FIG. 1 depicts an acoustic sensor 100 in accordance with an example.

FIG. 2 depicts a top, schematic view of a transducer with a cantilever-like diaphragm that may be used with the acoustic sensor device of FIG. 1 in accordance with one example.

The embodiments of the disclosed devices may assume various forms. Specific embodiments are illustrated in the drawing and hereafter described with the understanding that the disclosure is intended to be illustrative. The disclosure is not intended to limit the invention to the specific embodiments described and illustrated herein.

### DETAILED DESCRIPTION OF THE DISCLOSURE

Described herein are example acoustic sensor devices, such as microphones, configured for generation of a differential output using transducers (e.g., multiple MEMS transducers). The differential output is generated via multiple MEMS transducers. As described herein, the MEMS transducers may be positioned, oriented, and/or otherwise configured such that the MEMS transducers move in opposite directions in response to an input signal. For instance, the positioning, orientation, and configuration of the MEMS transducers may establish a sound path through the microphone such that the MEMS transducers move in opposite directions in response to the input signal. When the MEMS transducers have the same (or similar) configuration, such movement in opposite directions leads to the generation of equal and opposite outputs. The equal and opposite outputs may be used to generate a composite differential output.

The MEMS transducers may be disposed on respective dies while housed within a common enclosure or housing or package (e.g., under a same lid). For example, two MEMS transducers may be disposed in an in-plane configuration (e.g., side-by-side one another). However, the positioning, orientation, and configuration of the MEMS transducers may vary. For instance, the extent to, and the manner in, which the MEMS transducers are integrated may vary.

The disposition and/or other integration of the MEMS transducers under the same lid may lead to challenges during operation. Additional space may be warranted, for instance, to avoid sharp bends or turns in the sound path. However, in some cases, the additional space may increase the volume to an extent that shifts a resonant frequency of the cavity into the frequency band of interest.

Other challenges may arise in connection with the attempt to generate equal and opposite outputs. The MEMS transducers may have a common (e.g., cantilever-based) configuration. A common or same configuration for the MEMS transducers is useful for generation of output signals that are equal in amplitude and opposite in polarity. In some cases, the common configuration may include moving and fixed electrodes that include a single conductive layer (e.g., composed of, or otherwise including, polysilicon) disposed between two dielectric layers (e.g., composed of, or otherwise including, silicon nitride). Configuring the layers similarly may lead to the same amount of initial deflection for the moving electrodes, or cantilevers, of each MEMS transducer. However, differences between the MEMS transducers may arise from, e.g., manufacturing tolerance(s). Any such differences, along with the resulting deviations in respective outputs, may be addressed via calibration techniques involving, for instance, adjustments to the bias voltage and/or gain of one or both of the MEMS transducers.

Although described in connection with plate-shaped moving electrodes and electrodes with interdigitated fingers, a wide variety of transducer configurations may be used. Any type of MEMS directional transducer may be used.

The disclosed microphones are not limited to examples in which the MEMS transducers are identical (or intended to be identical). Accordingly, the disclosed microphones may include MEMS transducers have one or more intentional differences. For instance, the MEMS transducers may be configured differently to address an issue arising from the shape, size, or other characteristic of the flow path and/or the positioning or orientation of the MEMS dies within the device enclosure.

Although generally described in connection with microphones, the disclosed acoustic sensor devices may be used in other applications and contexts. For instance, the disclosed acoustic sensor devices may be useful in connection with accelerometers, gyroscopes, inertial sensors, pressure sensors, gas sensors, etc. The disclosed acoustic sensor devices are described in the context of excitation by sound waves. However, alternative or additional stimuli may excite the acoustic sensor devices in other contexts.

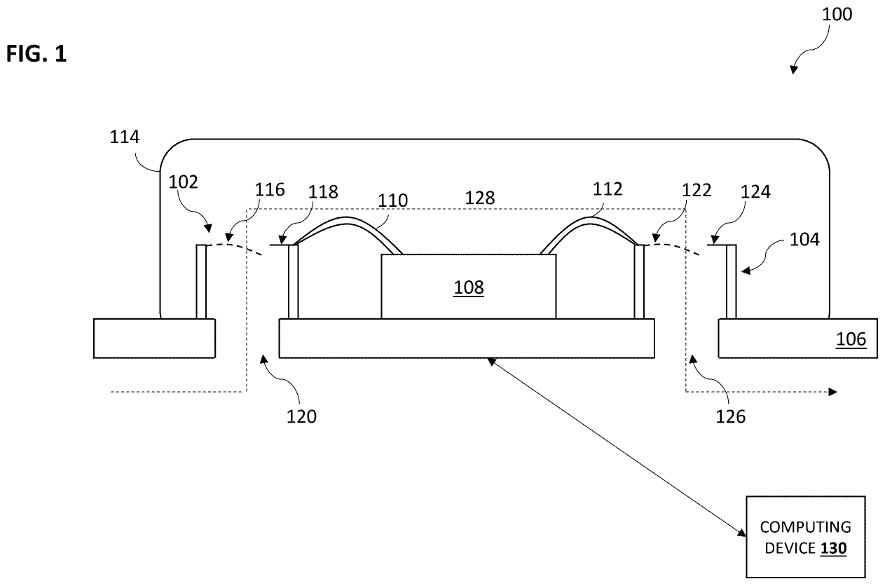

FIG. 1 depicts an acoustic sensor device 100 in accordance with one example. The acoustic sensor device 100 may be a microphone, and the acoustic sensor device 100 is sometimes referred to herein as “microphone” 100. In other examples, however, the acoustic sensor device 100 may be a suitable acoustic sensor device other than a microphone. Microphone 100 includes a first transducer (also sometime referred to herein as “left transducer”) 102 and a second transducer (also sometime referred to herein as “right transducer”) 104 supported by a substrate 106. Each of the left transducer 102 and the right transducer 104 may be a MEMS transducer. The substrate 106 may be or include a printed circuit board with one or multiple layers. The left transducer 102 and the right transducer 104 are coupled to an ASIC 108 by wire bonds 110 and 112 respectively. In some cases, the ASIC 108 may be or include a differential amplifier configured to amplify the difference between the signal generated by the left transducer 102 and the right transducer 104. In some cases, the ASIC 108 may include two discrete ASICs: a first ASIC coupled to the left transducer 102 and configured to amplify the signal from the left transducer 102 and a second ASIC coupled to the right transducer 104 and configured to amplify the signal from the right transducer 104. The ASIC 108 may be protected by a globtop (not shown in FIG. 1). The left transducer 102, the right transducer 104, and the ASIC 108 may be encapsulated by a lid or other enclosure 114. In some cases, the lid 114 may be composed of, or otherwise include, a metal. The substrate 106 and the lid 114 may form a housing of a package of the microphone 100.

The left transducer 102 may include a moving cantilever or electrode 116 and a fixed electrode 118. In some cases, the cantilever 116 may have an equilibrium position (also sometimes referred to as “initial deflection”) such that it is deflected downwards relative to the fixed electrode 118. The left transducer 102 may be mounted above a first (left) sound port 120 embedded in the substrate 106. The left sound port 120 may expose one side of the left transducer 102 to an ambient environment of the microphone 100. The right transducer 104 may include a moving cantilever, or electrode, 122 and a fixed electrode 124. In some cases, the cantilever 122 may have an equilibrium position (also sometimes referred to as “initial deflection”) such that it is deflected downwards relative to the fixed electrode 124. The right transducer 104 may be mounted above a second (right) sound port 126 embedded in the substrate 106. The right sound port 126 may expose one side of the right transducer 104 to the ambient environment of the microphone 100.

In some cases, the left transducer 102 and the right transducer 104 have the same configuration. In other cases, the transducers 102, 104 may have one or more differing characteristics, including, for example, structural characteristics (e.g., the size, shape, thickness, initial deflection, composition or configuration of the transducer) and/or operational characteristics (e.g., bias voltage or gain). The same configuration may thus include one or more operational adjustments to compensate for structural or other differences between the transducers 102, 104.

The left transducer 102 may generate or otherwise produce a first output signal when exposed to a sound wave traveling in an ambient environment of the microphone 100. The right transducer 104 may generate or otherwise produce a second output signal when exposed to the sound wave. The first output signal generated by the left transducer 102 and the second output signal generated by the right transducer 104 may have opposite polarities. For example, as a sound wave moves along a direction 128, the sound wave first hits or reaches the left sound port 120 of the microphone 100. As the sound wave enters the left sound port 120, the sound wave causes the cantilever 116 to bend upwards, closer to the fixed electrode 118. This decreases a gap between the cantilever 116 and fixed electrode 118 and increases a capacitance seen or detected by the left transducer 102. As a result, the first output signal generated by the left transducer 102 may be a positive signal. As the sound wave continues to traverse along the path 128, the sound wave then contacts or reaches the cantilever 122 and exits out of the right sound port 126. The cantilever 122 bends downward, away from fixed electrode 124. This increases a gap between cantilever 122 and fixed electrode 124 and decreases a capacitance seen or detected by the right transducer 104. As a result, the second output signal generated by the right transducer 102 may be a negative signal. When a sound wave traverses in the opposite direction, the right transducer 104 outputs a positive signal and the left transducer 102 outputs a negative signal. Thus, in either direction, if the left transducer 102 and right transducer 104 have the same or sufficiently similar configuration (e.g., structurally and/or operationally), then the transducers 102, 104 generate output signals that are equal in amplitude and opposite in polarity.

In some examples, the initial deflection of the cantilever 122 relative to the fixed electrode 124 of the right transducer 104 may be at least substantially the same as the initial deflection of the cantilever 116 relative to the fixed electrode 118 of the left transducer 104. For example, the left transducer 102 and the right transducer 104 may be configured such that the initial deflection of the cantilever 116 and the initial deflection of the cantilever 122 are within a predetermined (e.g., within 5 micrometers (μm) or within 10 μm) relative to each other. Such same or sufficiently similar initial deflections may ensure that, when the left transducer 102 and the right transducer 104 are exposed to a sound wave traveling in the ambient environment, the left transducer 102 and the right transducer 104 generate or otherwise produce signals that have at least substantially equal amplitudes with opposite polarities, in at least some examples.

In some examples, the first output signal of the left transducer 102 and the second output signal of the right transducer 104 are fed into the ASIC 108. The ASIC 108 may be a differential ASIC that may be configured to generate a composite output signal by effectively subtracting one signal from the other signal and amplify the resulting difference. A signal representative of the difference may then be provided to and processed by a computing device 130 that may be external to the microphone 100. The computing device 130 may comprise a codec, digital signal processor, microcontroller, and/or other processor, for example. In some example, the microphone 100 may be integrated into or otherwise used with an end product device, such as a smartphone, personal computer, headset, TV, robot, etc., and the computing device 130 may comprises a processor of the end-product device. In some cases, the ASIC 108 may also include an analog-to-digital converter configured to digitize the output signal such that the digitized signal is provided to the computing device 130 external to the external to the microphone 100.

In another example, the first output signal of the left transducer 102 and the second output signal of the right transducer 104 may be provided to the computing device 130 (e.g., after having been amplified and/or digitized by the ASIC 108). The computing device 130 may be configured to generate a composite output signal based on the first output signal of the left transducer 102 and the second output signal of the right transducer 104. For example, the computing device 130 may be configured to generate a composite output signal based on performing a subtraction operation between the first output signal of the left transducer 102 and the second output signal of the right MEMS transducer 104.

In an example, because the acoustic sensor device 100 includes two sound ports 120, 126, each of the transducers 102, 104 is exposed to the ambient environment on two opposing sides of the transducer 102, 104. Thus, each of the transducers 102, 104 may respond to a difference in pressure created on the opposing sides of the transducer 102, 104 when excited by a sound wave traveling in the ambient environment. As a result, each of the transducer 102, 104 may produce a directional (e.g., a dipole) output signal when excited by the sound wave traveling in the ambient environment. Accordingly, the composite output signal generated based on the output signals of the transducers 102, 104 may be a directional signal. The acoustic sensor device 100 may thus be a directional acoustic sensor device (e.g., a directional microphone).

In various examples, because the left transducer 102 and the right transducer 104 produce output signals with opposite polarities, the subtraction involving the output signal of the left transducer 102 and the output signal of the right transducer 104 may result in a composite output signal that is greater in amplitude than either of the individual output signals. Thus, for example, whereas the first output signal generated by the left transducer 102 may have a first amplitude and the second output signal generated by the right transducer 104 may have a second amplitude, the composite output signal generated by the computing device 130 or the ASIC 108 may have a third amplitude that is i) greater than the first amplitude of the first output signal and ii) greater than the second amplitude of the second output signal. In an example, the first amplitude of the first output signal and the second amplitude of the second output signal may be at least substantially equal to each other. In this case, the third amplitude of the composite output signal may greater by, at least approximately, a factor of two as compared to each of the first amplitude of the first output signal and the second amplitude of the second output signal.

Accordingly, in various examples, because the left transducer 102 and the right transducer 104 produce output signals of equal amplitudes but opposite polarities, the subtraction involving the output signal of the left transducer 102 and the output signal of the right transducer 104 may effectively double the amplitude of the resulting signal. Additionally, any signal components of equal amplitude, phase, and polarity on both output signals may effectively be cancelled. Such cancellation may help reduce unwanted noise that couples onto the outputs of both the left transducer 102 and the right transducer 104, as well reduce distortion due to non-linearities during operation of the transducers 102, 104. As described above, in some examples, the ASIC 108 may instead be or include two separate ASICs, respectively amplifying the output of the left transducer 102 and the right transducer 104. The two signals may then be processed (e.g., subtracted) in the computing device 130 external to the microphone 100.

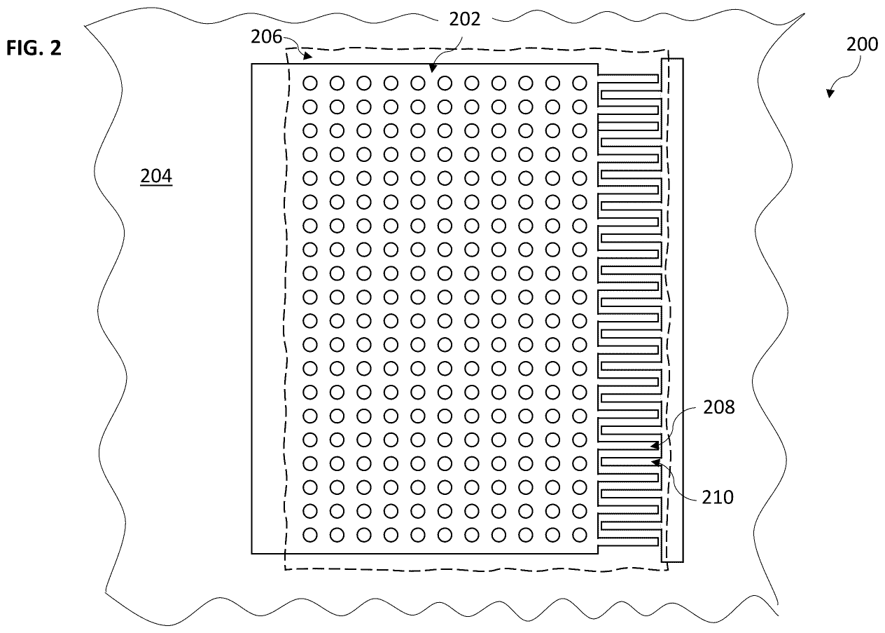

FIG. 2 depicts a top, schematic view of a transducer 200 with a cantilever-like diaphragm in accordance with one example. The transducer 200 may be a MEMS transducer. In some cases, the transducer 200 may be used as one or each of the transducers 102, 104 of FIG. 1. Alternative or additional transducers may be used in other cases.

The transducer 200 includes a diaphragm, or moving electrode, 202 that is anchored to a surrounding substrate 204. In this example, the diaphragm is configured as a cantilever, and may be referred to herein as such. The substrate 204 has a cavity 206 above which the cantilever 202 is positioned. The cavity 206 may be formed through various microfabrication practices, including, for instance, deep reactive ion etching (DRIE). In the illustrated example, the cantilever 202 includes a porous plate-like structure. In another example, the cantilever 202 may include a nonporous plate-like structure, such as a solid plate without holes.

Attached to the free end of the cantilever 202 are one or more moving fingers 208. The fingers 208 are configured so that the fingers move with the cantilever 202. The cantilever 202 and fingers 208 may thus be considered a single composite moving structure, or electrode. The moving electrode includes at least one conductive layer.

The moving electrode 202 is disposed alongside a set of fixed fingers, or a fixed electrode, 210. The fixed electrode 210 is anchored to the substrate 204 and suspended over the cavity 206. In some cases, the fixed electrode 210 is shorter in length than the moving electrode 202. As the transducer 200 is excited by a sound wave, the fixed fingers 210 do not move, or move relatively less than the fingers 208 of the electrode 202. The fingers 210 include at least one conductive layer such that a capacitance is formed between the fingers 208 and 210. As the cantilever 202 vibrates, the gap between the fingers 208 and 210 changes. This change, in turn, creates a change in capacitance that can be converted into an electronic signal and amplified by an ASIC.

The transducer 200 may be configured such that the transducer has a first resonant frequency in the audio band. For example, the first resonant frequency of the transducer 200 may fall in a range from about 1 kHz to about 5 kHz.

The cantilever 202 is illustrated as a rectangle for ease of illustration. Other shapes or profiles may be used. For instance, the cantilever 202 may have a top profile that is rectangular, circular, elliptical, triangular, or any other geometrical shape. Similarly, the cavity 206 may have a top profile that is rectangular, circular, elliptical, triangular, or any other geometrical shape. The fingers 208 may cover the entire perimeter of the free ends of the cantilever 202 or one or more smaller subsections. The fingers 208 may have a thickness that is different than the thickness of cantilever 202 and/or fingers 210. The fingers 208 and/or 210 may have a top profile that is rectangular, circular, elliptical, triangular, or any other geometrical shape. In some cases, the gap between the fingers 208 and 210 falls in a range from about 1 μm to about 8 μm, the length of fingers 208 and 210 falls in a range from about 50 μm to about 250 μm, and/or the width of fingers 208 and 210 falls in a range from about 1 μm to about 20 μm. In other cases, the length and/or width of the fingers 208 and/or 210 may vary relative to one another. For example, the fingers 208 and/or 210 on at least one of the free sides of cantilever 202 may have a different length than the remaining sides. In some examples, the gap defined by at least one pairing of the fingers 208 and 210 along the perimeter of the cantilever 202 may be different than that of another pairing of fingers. In some cases, the cantilever 202 may include two or more plate-like cantilevers that are coupled electrically and/or mechanically.

In some examples, the left transducer 102 and the right transducer 104 of microphone 100 may or may not have a similar configuration to that of transducer 200. For instance, the cantilever 202 and moving fingers 208 of the transducers 102, 104 may have an initial deflection downwards or upwards relative to the fixed fingers 210. In other examples, the left transducer 102 and right transducer 104 may have configurations (e.g., cantilever-like configurations) that are different from each other. However, in such cases, the resting deflection of the cantilevers in the transducers 102 and 104 are in the same direction (i.e., upward or downward) relative to the fixed electrodes.

Examples are described in which an acoustic sensor device includes multiple (e.g., two) transducers configured to move in opposite directions with respect to each other when exposed to a sound wave traveling in an ambient environment of the acoustic sensor device. The two transducers may thus generate or otherwise produce respective output signals that are opposite in polarity with respect to each other. A composite output signal may then be generated based on the respective output signals of the two transducers. For example, the acoustic sensor device may include an integrated circuit configured to generate a composite output signal based on the respective output signals of the two transducers. In another example, the respective output signals may be provided to an external computing device, and a composite output signal based on the respective output signals may be generated by the external computing device. In an example, the composite output signal may be generated based on a subtraction operation involving the two output signals (i.e., subtracting one of the output signals from the other one of the output signals). Because the respective output signals are opposite in polarity, the composite signal may have an amplitude that is greater than an amplitude of each of the individual output signal.

In some examples, the two transducers may be configured such that the respective output signals are at least substantially equal in amplitude with respect to each other. For example, the two transducers may be configured such that the two transducers have structures that are the same as each other or are at least substantially similar to each other. As another example, the two transducers may comprise respective cantilever structures that have initial (equilibrium) deflections that are the same as each other or are within a small, predetermined range (e.g., 5 μm or 10 μm) relative to each other. As yet another example, the two transducers may be symmetrically placed over respective sound ports formed in a substrate of the acoustic sensor device. In various examples, because the respective output signals are at least substantially equal in amplitude and opposite in polarity, the composite output signal generated based on a subtraction operation involving the two output signals may have an amplitude that is double of the amplitude of each of the individual output signals. Further, signal components of equal amplitude, phase, and polarity on the individual output signals may effectively be cancelled in the composite output signal. Such cancellation may help reduce unwanted noise that couples onto the outputs of the two transducers, as well reduce distortion due to non-linearities during operation of the two transducers, in at least some examples.

The term “about” is used herein in a manner to include deviations from a specified value that would be understood by one of ordinary skill in the art to effectively be the same as the specified value due to, for instance, the absence of appreciable, detectable, or otherwise effective difference in operation, outcome, characteristic, or other aspect of the disclosed methods and devices.

The present disclosure has been described with reference to specific examples that are intended to be illustrative only and not to be limiting of the disclosure. Changes, additions and/or deletions may be made to the examples without departing from the spirit and scope of the disclosure.

The foregoing description is given for clearness of understanding only, and no unnecessary limitations should be understood therefrom.

What is claimed is:

1. An acoustic sensor device, comprising:
a substrate;
a first transducer supported by the substrate, the first transducer configured to generate a first output signal when exposed to a sound wave; and
a second transducer supported by the substrate, the second transducer configured to generate a second output signal when exposed to the sound wave,
wherein the first transducer and the second transducer are configured such that the first output signal generated by the first transducer and the second output signal generated by the second transducer are opposite in polarity.

2. The acoustic sensor device of claim 1, wherein each of the first transducer and the second transducer comprises a microelectromechanical system (MEMS) transducer.

3. The acoustic sensor device of claim 2, wherein each of the first transducer and the second transducer comprises a cantilever structure.

4. The acoustic sensor device of claim 3, wherein:
the first transducer comprises a first cantilever having a first initial deflection on one side of the first cantilever; and
the second transducer comprises a second cantilever having a second initial deflection on one side of the second cantilever, wherein the first initial deflection of the first cantilever and the second initial deflection of the second cantilever are configured to be within a predetermined range with respect to each other.

5. The acoustic sensor device of claim 3, further comprising a package, wherein the substrate forms one side of the package, and wherein the package further includes a lid placed over the substrate, the lid encapsulating the first transducer and the second transducer inside package.

6. The acoustic sensor device of claim 5, further comprising:
a first sound port configured to expose one side of the first transducer to an ambient environment; and
a second sound port configured to expose one side of the second transducer to the ambient environment,
wherein
the first sound port is formed in the substrate, and
the second sound port is formed in the substrate such that the first sound port and the second sound port are formed on a same side of the package of the acoustic sensor device.

7. The acoustic sensor device of claim 6, wherein:
the first transducer comprises a first cavity placed over the first sound port formed in the substrate; and
the second transducer comprises a second cavity placed over the second sound port formed in the substrate.

8. The acoustic sensor device of claim 3, wherein the first transducer and the second transducer are configured such that the first transducer and the second transducer move in opposite directions with respect to each other when exposed to the sound wave.

9. The acoustic sensor device of claim 1, further comprising an integrated circuit coupled to the first transducer and the second transducer, the integrated circuit configured to:
receive the first output signal generated by the first transducer, wherein the first output signal has a first amplitude;
receive the second output signal generated by the second transducer, wherein the second output signal has a second amplitude; and
generate a composite output signal based on the first output signal and the second output signal, wherein the composite output signal has a third amplitude that is i) greater than the first amplitude of the first output signal and ii) greater than the second amplitude of the second output signal.

10. The acoustic sensor device of claim 9, wherein the integrated circuit is configured to generate the composite output signal by performing a subtraction operation between the first output signal generated by the first transducer and the second output signal generated by the second transducer.

11. The acoustic sensor device of claim 9, wherein the first transducer and the second transducer are configured such that the first amplitude of the first output signal and the second amplitude of the second output signal are equal to each other, and wherein the third amplitude of the composite output signal is greater than each of the first amplitude of the first output signal and the second amplitude of the second output signal by a factor of two.

12. An acoustic sensor device, comprising:
a substrate;
a first microelectromechanical system (MEMS) transducer supported by the substrate, the first MEMS transducer configured to generate a first output signal when exposed to a sound wave; and
a second MEMS transducer supported by the substrate, the second MEMS transducer configured to generate a second output signal when exposed to the sound wave,
wherein the first MEMS transducer and the MEMS second transducer are configured such that the first MEMS transducer and the second MEMS transducer move in opposite directions with respect to each other when exposed to the sound wave.

13. The acoustic sensor device of claim 12, wherein each of the first MEMS transducer and the second MEMS transducer comprises a cantilever structure.

14. The acoustic sensor device of claim 12, wherein:
the first MEMS transducer comprises a first cantilever having a first initial deflection on one side of the first cantilever; and
the second MEMS transducer comprises a second cantilever having a second initial deflection on one side of the second cantilever, wherein the first initial deflection of the first cantilever and the second initial deflection of the second cantilever are configured to be within a predetermined range with respect to each other.

15. The acoustic sensor device of claim 12, further comprising a package, wherein the substrate forms one side of the package, and wherein the package further includes a lid placed over the substrate, the lid encapsulating the first MEMS transducer and the second MEMS transducer inside package.

16. The acoustic sensor device of claim 15, further comprising:
a first sound port configured to expose one side of the first MEMS transducer to an ambient environment; and
a second sound port configured to expose one side of the second MEMS transducer to the ambient environment,
wherein
the first sound port is formed in the substrate, and
the second sound port is formed in the substrate such that the first sound port and the second sound port are formed on a same side of the package of the acoustic sensor device.

17. The acoustic sensor device of claim 16, wherein:
the first MEMS transducer comprises a first cavity placed over the first sound port formed in the substrate; and
the second MEMS transducer comprises a second cavity placed over the second sound port formed in the substrate.

18. The acoustic sensor device of claim 12, further comprising an integrated circuit coupled to the first MEMS transducer and the second MEMS transducer, the integrated circuit configured to:
receive the first output signal generated by the first MEMS transducer, wherein the first output signal has a first amplitude;
receive the second output signal generated by the second MEMS transducer, wherein the second output signal has a second amplitude; and
generate a composite output signal based on the first output signal and the second output signal, wherein the composite output signal has a third amplitude that is i) greater than the first amplitude of the first output signal and ii) greater than the second amplitude of the second output signal.

19. The acoustic sensor device of claim 18, wherein the integrated circuit is configured to generate the composite output signal by performing a subtraction operation between the first output signal generated by the first MEMS transducer and the second output signal generated by the second MEMS transducer.

20. The acoustic sensor device of claim 19, wherein the first MEMS transducer and the second MEMS transducer are configured such that the first amplitude of the first output signal and the second amplitude of the second output signal are equal to each other, and wherein the third amplitude of the composite output signal is greater than each of the first amplitude of the first output signal and the second amplitude of the second output signal by a factor of two.
